(19) United States
(12) Patent Application Publication
(10) Pub. No.: US 2011/0205710 A1
(43) Pub. Date: Aug. 25, 2011

(54) ELECTRONIC DEVICE

(76) Inventors: Naoto Kondo, Tokyo (JP); Satoshi Sato, Tokyo (JP)

(21) Appl. No.: 13/033,142

(22) Filed: Feb. 23, 2011

(30) Foreign Application Priority Data
Feb. 24, 2010 (JP) 2010-038647

(51) Int. Cl. H05K 7/20

(52) U.S. Cl. 361/714

(57) ABSTRACT

Provided is an electronic device that can reduce a material cost and the number of members to eliminate complex processing. The electronic device has a circuit board on which circuit elements are provided, and a shield case that accommodates the circuit board. The shield case has a frame. The frame has a side plate part having side plates for holding and covering the outer periphery of the circuit board, coupling parts extending parallel to a plane of the circuit board and connecting with at least two of the side plates, and contact parts connected to the coupling parts and directly contacting the circuit elements. The shield case releases the heat produced from the circuit elements via the contact parts and the coupling parts.

### CROSS REFERENCE TO RELATED APPLICATIONS

This application is entitled to and claims the benefit of Japanese Patent Application No. 2010-038647, filed on Feb. 24, 2010, the disclosure of which including the specification, drawings and abstract, is incorporated herein by reference in its entirety.

### TECHNICAL FIELD

The present invention relates to an electronic device having a shield case for protecting an electronic circuit board.

### BACKGROUND ART

An electronic circuit board for an electronic device such as a satellite radio tuner has been accommodated in a shield case for protection from external electric field and external magnetic field. A shield case of this kind is formed primarily with a container-shaped case that holds and covers the side planes of an electronic circuit board, and a cover that covers the uncovered part of an electronic circuit board attached to the container-shaped case.

Now, the configuration of a shield case used in a conventional electronic device will be described with reference to FIG. 1 to FIG. 6. FIG. 1 shows a perspective view of a configuration of conventional container-shaped case 10. FIG. 2 shows a plan view of a configuration of conventional container-shaped case 10. FIG. 3 shows a plan view of a configuration of conventional circuit board 20. FIG. 4 shows a plan view of a configuration of container-shaped case 10 to which conventional circuit board 20 is attached.

As shown in FIG. 1 and FIG. 2, conventional container-shaped case 10 of a shield case is a metallic case formed in a container shape to hold circuit board 20 (described later). Container-shaped case 10 has side plate part 11 and bottom plate 12. Bottom plate 12 has recess 121, opening 122 and opening 123, and also functions as a cover to cover the lower plane of circuit board 20. Recess 121 is a recess that creates a projection on the circuit board 20 side, and is placed in a location matching synchronous dynamic random access memory (“SDRAM”) 24 on circuit board (see FIG. 6). Opening 122 is provided in recess 121. Side plate part 11 and bottom plate 12 are formed integrally.

As shown in FIG. 3, circuit board 20 is a printed circuit board (“PCB”) for a satellite radio tuner. Circuit board 20 has circuit board main body 21, radio frequency (“RF”) tuner 22, baseband integrated circuit (“IC”) 23, connector 25 having connector pins, and connecting parts 26. A plurality of connecting parts 26 for soldering are provided on the outer periphery of circuit board main body 21. Also, coaxial cable 27 for antenna connection is provided in circuit board main body 21 of circuit board 20.

As shown in FIG. 4, circuit board 20 is attached to container-shaped case 10. Circuit board main body 21 of circuit board 20 is fitted with side plate part 11 of container-shaped case 10. Furthermore, circuit board main body 21 is fixed to side plate part 11 of container-shaped case 10 by soldering in connecting parts 26. In this way, only the outer periphery of circuit board main body 21 of circuit board 20 is held by container-shaped case 10.

Next, shield case 1, which includes container-shaped case 10, will be described with reference to FIG. 5 and FIG. 6. FIG. 5 shows a plan view of a configuration of shield case 1 in which conventional circuit board 20 is accommodated. FIG. 6 is a VI-VI cross sectional view of shield case 1 of FIG. 5 in which circuit board 20 is accommodated.

As shown in FIG. 5 and FIG. 6, shield case 1 has container-shaped case 10 and cover 30. Cover 30 is a metallic cover that covers the uncovered part on the upper plane of circuit board 20 attached to container-shaped case 10. Cover 30 has cover main body 31, recess 32 and opening 33. Recess 32 is a recess that creates a projection on the container-shaped case 10 side, and is placed in a location to match baseband IC 23 on circuit board 20. Opening 33 is provided in recess 32. Referring to FIG. 5 and FIG. 6, assume that circuit board 20 is a type to which connector 27A for antenna connection is connected, instead of coaxial cable 27.

As shown in FIG. 6, in shield case 1, heat-sink sheet 231 is applied over baseband IC 23. Baseband IC 23 is placed to contact recess 32 of cover 30 indirectly via heat-sink sheet 231. Opening 33 provides a peep hole for checking against forgetting applying heat-sink sheet 231. By this means, baseband IC 23 is thermal-coupled with cover 30 that serves as a heat sink, via heat-sink sheet 231. The heat of baseband IC 23 travels to cover 30 and container-shaped case 10, via heat-sink sheet 231, and is released in the air.

Likewise, in shield case 1, heat-sink sheet 241 is applied over SDRAM 24. SDRAM 24 is placed to contact recess 121 of bottom plate 12 indirectly via heat-sink sheet 241. Opening 122 provides a peep hole for checking against forgetting applying heat-sink sheet 241. By this means, SDRAM 24 is thermal-coupled with bottom plate 12 that serves as a heat sink, via heat-sink sheet 241. The heat of SDRAM 24 travels to bottom plate 12 and side plate part 11, via heat-sink sheet 241, and is released in the air.

Also, a configuration has been known in which a shield case has a contact part that is formed by bending part of a cover part, and in which this contact part is placed in contact with circuit elements such as transistors (see, for example, patent literature 1). The heat produced by these circuit elements travels over the entirety of the shield case via the contact part and is released.

Patent Literature 1: Japanese Patent Application Laid-Open No. 2004-241573

### SUMMARY OF INVENTION

However, with conventional shield case 1, container-shaped case 10 is formed with a metallic plate that is 0.5 mm thick and that is thicker than the plate thickness of cover 30, and this makes the cost material high and makes cost reduction difficult.

Also, with shield case 1, processing for forming recess 121 in container-shaped case 10 is required, so as to place cover 30 and container-shaped case 10 in contact with heat-sink sheets 231 and 241. In addition, processing for forming, in cover 30 and container-shaped case 10, opening 33 and 122 for checking against forgetting applying heat-sink sheet 231 and 241 is required. Likewise, with a conventional shield case having a contact part, processing for forming a contact part in a cover needs to be performed. Consequently, there are a large number of members to require complex processing.

It is therefore an object of the present invention to provide an electronic device that can reduce the material cost of a shield case and reduce the number of members to require complex processing.

In order to achieve the above object, an electronic device according to the present invention has a circuit board on which a circuit element is provided, and a shield case that accommodates the circuit board, and, in this electronic device, the shield case has a frame which comprises a side plate part having a plurality of side plates holding and covering an outer periphery of the circuit board, a coupling part extending parallel to a plane of the circuit board and connecting with at least two of the side plates, and a contact part connected with the coupling part and directly contacting the circuit element, and the shield case releases heat produced from the circuit element via the contact part and the connecting part of the frame.

With the present invention, it is possible to reduce the material cost of a shield case and reduce the number of members to require complex processing.

### BRIEF DESCRIPTION OF DRAWINGS

FIG. 1 is a perspective view of a conventional container-shaped case;

FIG. 2 is a plan view of a conventional container-shaped case;

FIG. 3 is a plan view of a conventional circuit board;

FIG. 4 is a plan view of a container-shaped case to which a conventional circuit board is attached;

FIG. 5 is a plan view of a shield case in which a conventional circuit board is accommodated;

FIG. 6 is a VI-VI cross sectional view of the shield case of FIG. 5 in which a conventional circuit board is accommodated;

FIG. 7 is a perspective view of a shield case to use for an electronic device according to an embodiment of the present invention;

FIG. 8 is a plan view of a frame according to an embodiment;

FIG. 9 is a plan view of a circuit board according to an embodiment;

FIG. 10 is a plan view of a frame to which a circuit board according to an embodiment is attached;

FIG. 11 is an XI-XI cross sectional view of the frame of FIG. 10 to which a circuit board is attached; and

FIG. 12 is an XII-XII cross sectional view of the frame of FIG. 10 to which a circuit board is attached.

### DETAILED DESCRIPTION OF PREFERRED EMBODIMENTS

Embodiments of the present invention will be described below in detail with reference to the accompanying drawings. However, the scope of the present invention is not limited to the illustrated examples.

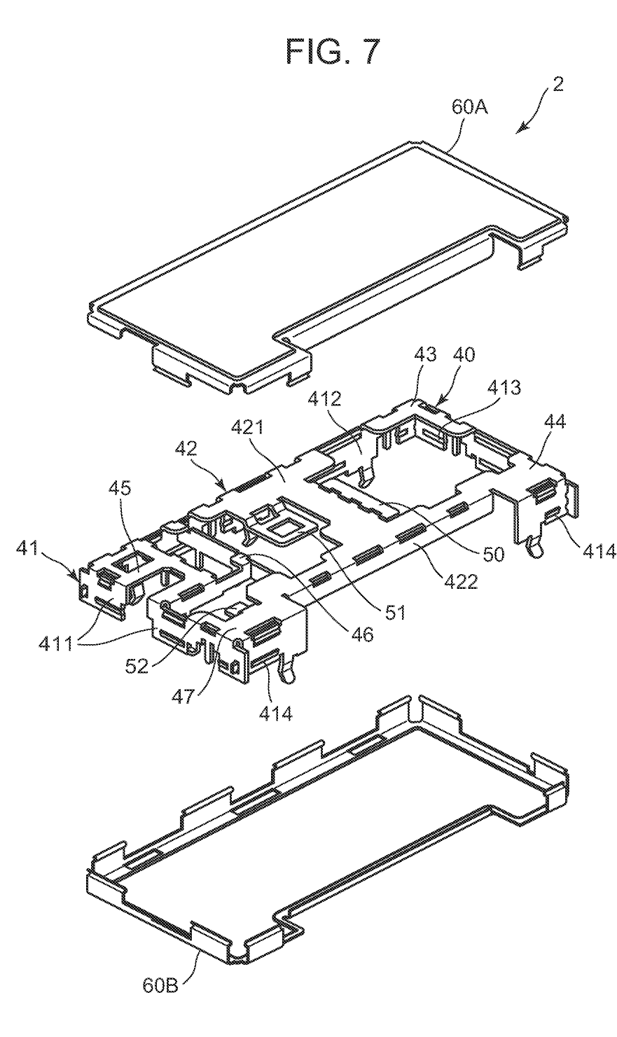

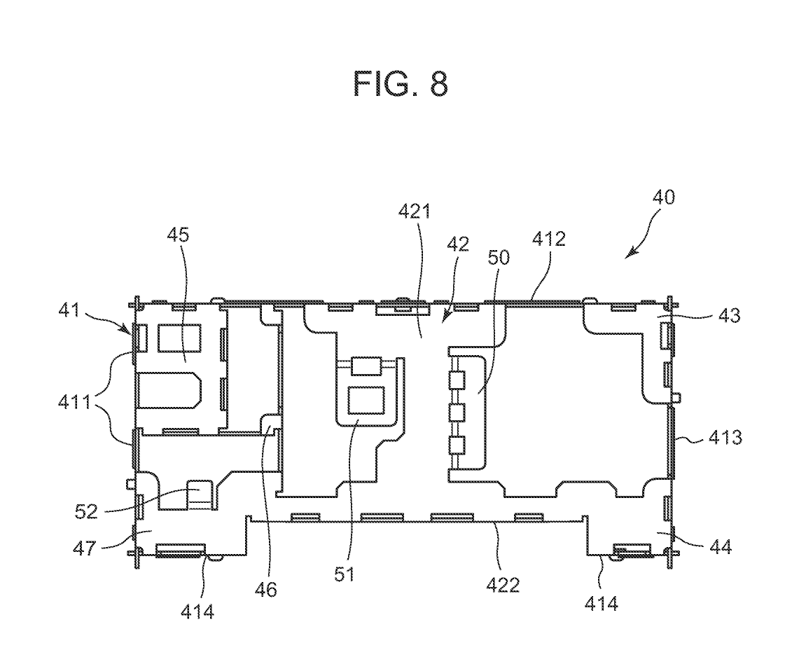

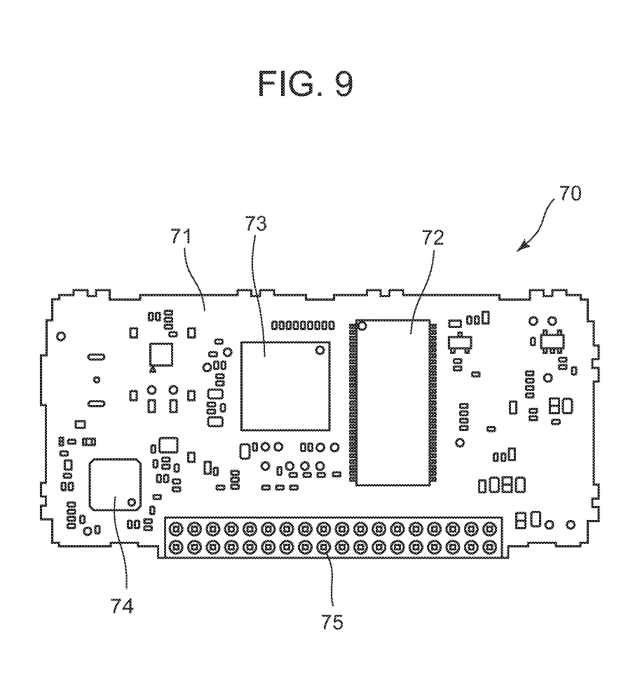

First, a configuration of shield case 2 to use for an electronic device according to the present embodiment will be described using FIG. 7 to FIG. 9. FIG. 7 shows a perspective view of a configuration of shield case 2. FIG. 8 shows a plan view of a configuration of frame 40. FIG. 9 shows a plan view of a configuration of circuit board 70.

The electronic device according to the present embodiment has shield case 2 and circuit board 70. Shield case 2 accommodates circuit board 70. Circuit board 70 is a circuit board for a tuner of a vehicle-mounted satellite radio receiver. Shield case 2 protects circuit board 70 from external electric field and external magnetic field. However, this is by no means limiting, and the electronic device may be a different electronic device from a vehicle-mounted satellite radio receiver.

As shown in FIG. 7, shield case 2 has frame 40 and covers 60A and 60B. Frame 40 is a frame for holding and covering the outer periphery of circuit board 70. Frame 40 is metallic, has a plate thickness of 0.5 mm, and uses ZE-38 (lead-free steel plate for solder), for example.

Cover 60A is a cover for covering the uncovered part in the upper plane of circuit board 70 attached to frame 40. Cover 60B is a cover for covering the uncovered part of the lower surface of circuit board 70 attached to frame 40. Covers 60A and 60B3 are made of SPTE (tinplate) and suchlike metal.

As shown in FIG. 7 and FIG. 8, frame 40 has side plate part 41, coupling parts 42, 43, 44, 45, 46 and 47, and contact parts 50, 51 and 52. The individual parts of frame 40 are formed integrally. Side plate part 41 holds and covers the outer periphery of circuit board 70. Side plate part 41 has side plates 411, 412, 413 and 414.

Coupling parts 42-47 are provided to extend parallel to the open plane of side plate part 41 (circuit board 70) and reinforce side plate part 41. Coupling parts 42-47 each provided within the open plane of side plate part 41 and are coupled with at least two of side plates 411-414. For example, coupling part 42 is coupled with side plates 412 and 414. Coupling part 43 is coupled with side plates 412 and 413. Coupling part 44 is coupled with side plates 413 and 414. Coupling part 45 is coupled with side plates 411 and 412. Coupling part 46 is coupled with side plates 411, 412 and 414. Coupling part 47 is coupled with side plates 411 and 414.

Coupling parts 42-47 are each formed with at least one of a planar plate that is parallel to the open plane of side plate part 41 (circuit board 70), and a partitioning plate that is parallel to the side plate of side plate part 41. For example, coupling part 42 has planar plate 421 and partitioning plate 422. Planar plate 421 is a flat plate that is coupled to the center of side plate part 41 in the longitudinal direction. Partitioning plate 422 is connected to planar plate 421 and is a partitioning plate that is placed in a location to match an edge of the connector 75 area in circuit board 70 (described later). Partitioning plate 422 is formed by bending part of planar plate 421. Coupling parts 42-47 are arranged substantially in a lattice pattern in the planar plane of side plate part 41.

Contact parts 50-52 are metallic springs to be placed in direct contact with the circuit elements of circuit board 70. Contact parts 50 and 51 are provided in coupling part 42. Contact part 52 is provided in coupling part 47. Even when there is a vibration or shock, contact parts 50-52, by their spring structure, are kept in a state of contacting circuit elements of circuit board 70. Contact parts 50-52 and the circuit elements of circuit board 70 are placed in direct contact so that a heat-sink sheet is not necessary, but it is nevertheless possible to use a heat sink sheet if necessary.

As shown in FIG. 9, circuit board 70 has circuit board main body 71, SDRAM 72, baseband IC 73, RF tuner 74, and connector 75 having connector pins. A coaxial cable for antenna connection (not shown) or a connector (not shown) is connected to circuit board 70.

SDRAM 72, baseband IC 73, and RF tuner 74 are arranged on the same one plane of circuit board main body 71. SDRAM 72, baseband IC 73 and RF tuner 74 are circuit elements having relatively high calorific values. On the plane of circuit board main body 71 opposite to the plane where SDRAM 72 and others are placed, a micro computer (not shown) and suchlike circuit elements having relatively low calorific values are provided. Contact parts 50-52 are placed in locations to match SDRAM 72, baseband IC 73, and RF tuner 74, respectively.

As shown in FIG. 7, covers 60A and 60B have a shape to cover the planar plane of circuit board 70 entirely, except for the part of circuit board 70 to match connector 75, because a heat-sink sheet is not necessary in shield case 2, and covers 60A and 60B therefore do not need to have openings for checking a heat-sink sheet. Also, since frame 40 itself has contact parts 50-52, it is not necessary to provide contact parts in covers 60A and 60B.

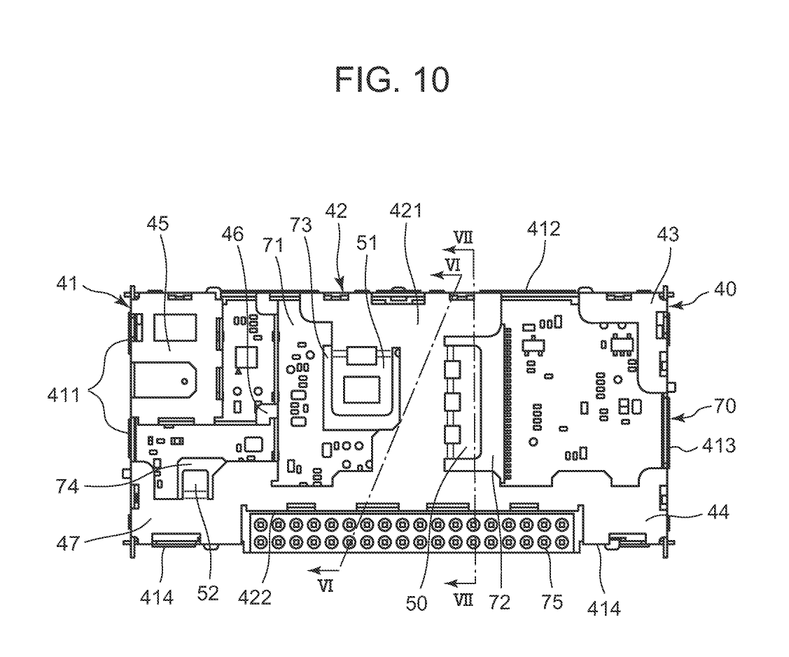

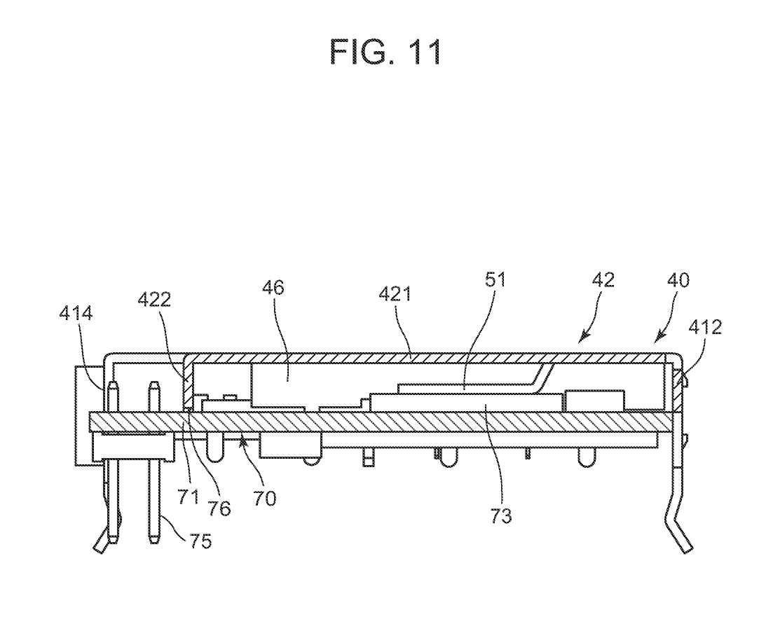

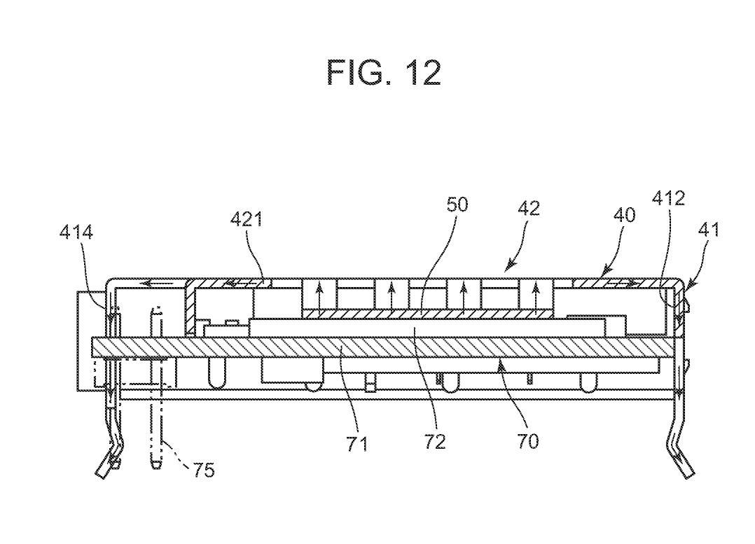

Next, frame 40, to which circuit board 70 is attached, will be explained with reference to FIG. 10-FIG. 12. FIG. 10 is a plan view of frame 40 to which circuit board 70 is attached. FIG. 11 is an XI-XI cross sectional view of frame 40 of FIG. 10 to which circuit board 70 is attached. FIG. 12 is an XII-XII cross sectional view of frame 40 of FIG. 10 to which circuit board 70 is attached.

As shown in FIG. 10, circuit board 70 is attached to frame 40. To be more specific, circuit board 70 is fitted with frame 40 and is fixed by being soldered with frame 40 in a plurality of connecting points. Also, a coaxial cable for antenna connection or a connector is attached to circuit board 70. Also, covers 60A and 60B are attached to frame 40, to which circuit board 70 is attached. To be more specific, covers 60A and 60B are mated with and locked in the exterior of side plate part 41 and partitioning plate 422 of frame 40, to which circuit board 70 is attached.

As shown in FIG. 11, partitioning plate 422 of coupling part 42 of frame 40 is placed to directly contact grounding part 76 near connector 75 on circuit board 70. Grounding part 76 is a soldering part kept at ground potential. Consequently, the potential of frame 40 is kept at ground potential on the whole.

Also, in frame 40 to which circuit board 70 is attached, contact parts 50-52 are placed to directly contact SDRAM 72, baseband IC 73 and RF tuner 74, respectively. For example, as shown in FIG. 11, contact part 51 directly contacts baseband IC 73.

The heat produced in SDRAM 72, baseband IC 73 and RF tuner 74 passes contact parts 50-52 and coupling parts 42 and 47 in order, travels to side plate part 41, covers 60A and 60B, and is released in the air. That is to say, contact parts 50-50, coupling parts 42 and 47, side plate part 41 and covers 60A and 60B constitute a heat sink for the heat produced in SDRAM 72, baseband IC 73 and RF tuner 74. For example, as shown in FIG. 12, the hear produced in SDRAM 72 travels to side plates 412 and 414 of side plate part 41 and covers 60A and 60B, via contact part 50 and planar plate 421 of coupling part 42, and is released into the air. That is to say, contact part 50, planar plate 421 of coupling part 42, side plates 412 and 414 of side plate part 41, and covers 60A and 60B constitute a heat sink for the heat produced in SDRAM 72.

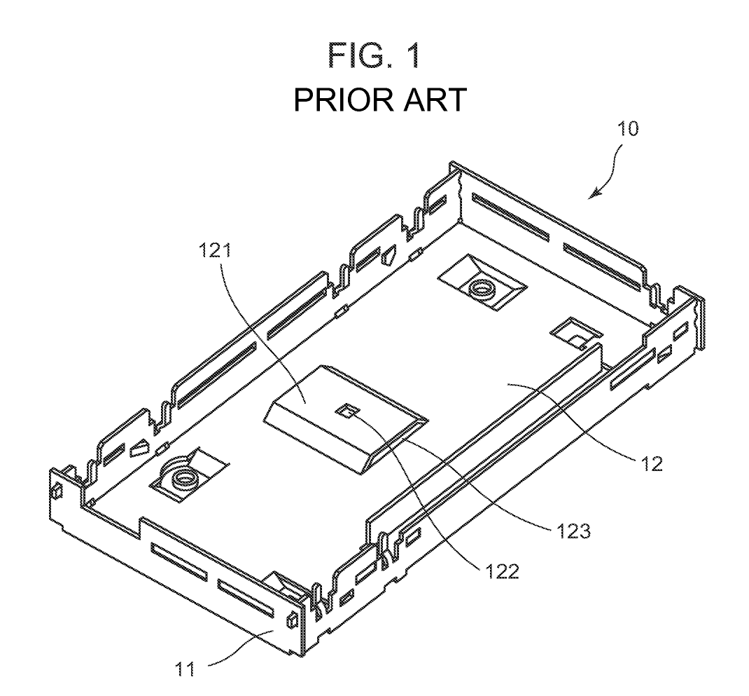

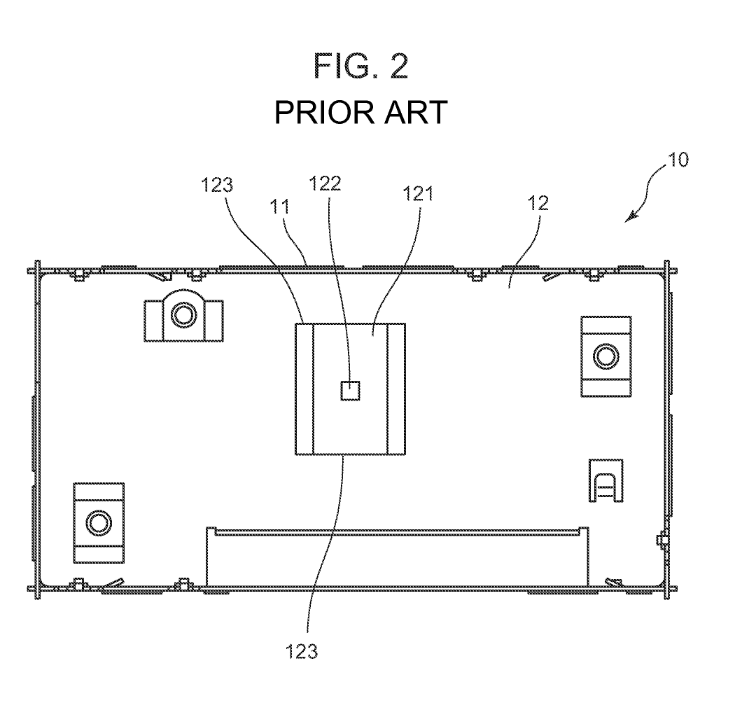

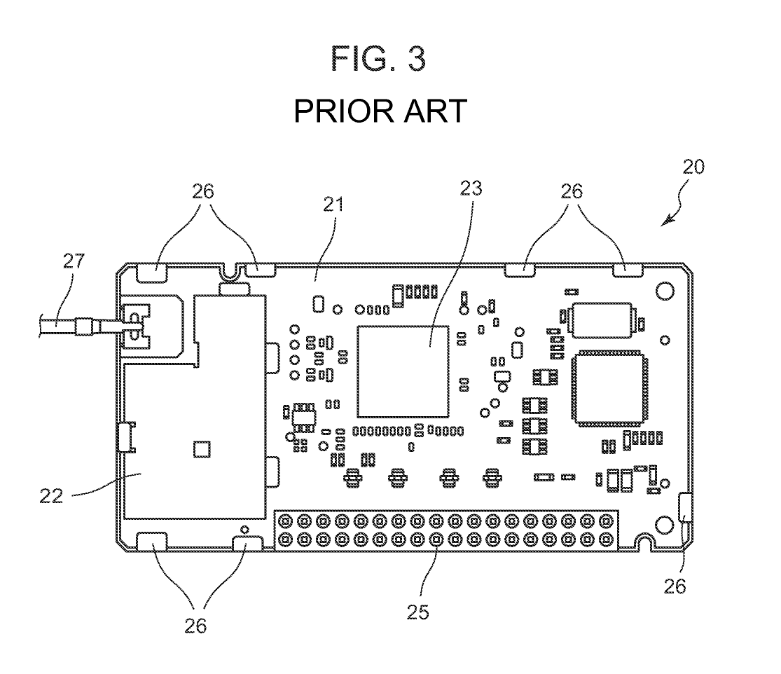

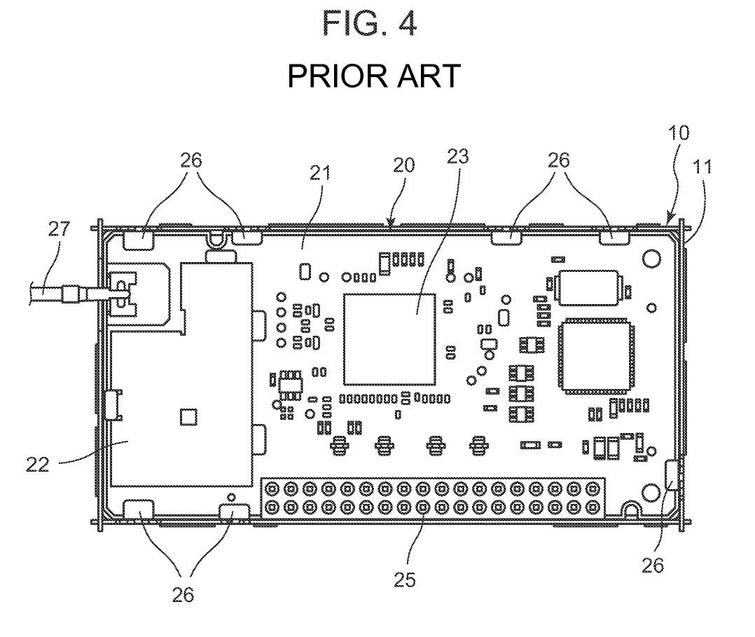

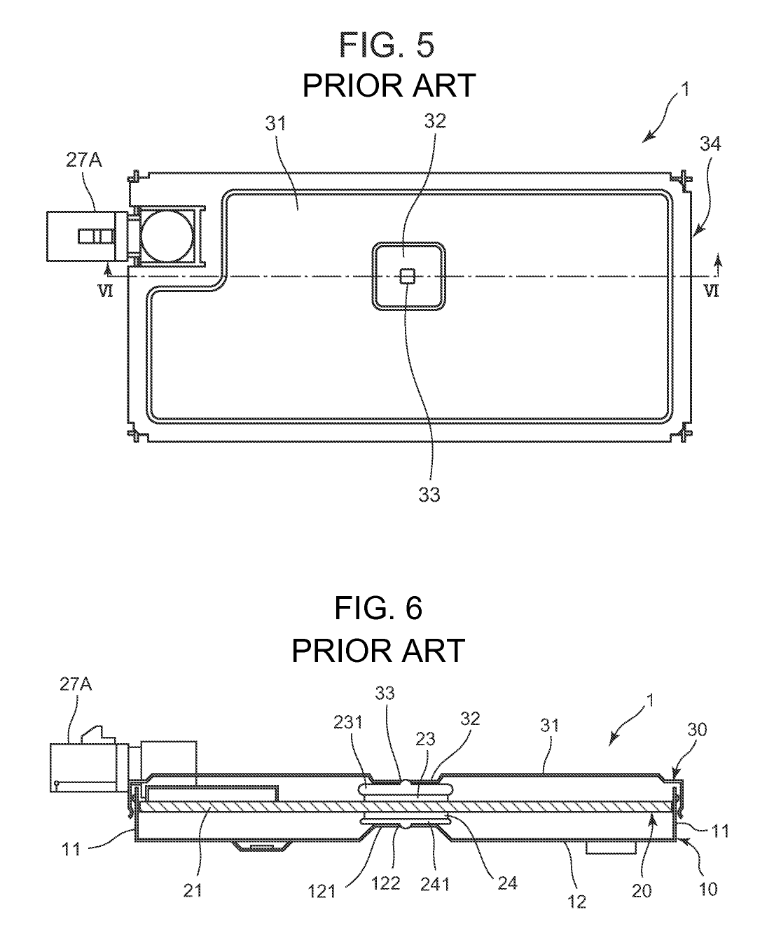

Consequently, with the present embodiment, frame 40 of shield case 2 for an electronic device has coupling parts 42-47, that are coupled with at least two of side plate 412-414 of side plate part 41, and contact parts 50-52. Consequently, a bottom plate having a thick plate thickness such as container-shaped case 10 shown in FIG. 1 is not provided in frame 40, so that the material cost of shield case 2 can be reduced. In addition, contact parts and openings are not formed in covers 60A and 60B, so that the number of members to require complex processing can be reduced.

Also, side plate part 41 can be reinforced by means of coupling parts 42-47, so that the vibration and shock that is applied to shield case 2 and then travels to circuit board 70 can be reduced. Consequently, frame 40 can be made tough against the warp or twist of a circuit board in shied case 2 due to the vibration or shock applied to shield case 2 and also can be made tough against the stress applied against the mounted parts and connecting parts of circuit board main body 71.

Also, frame 40 has contact parts 50-42 connected to coupling parts 42 and 47. Contact parts 50-52 are placed in direct contact with SDRAM 72, baseband IC 73 and RF tuner 74. Consequently, by means of these contact parts 50-52, the heat produced in SDRAM 72, baseband IC 73 and RF tuner 74 travels to side plate part 41 and covers 60A and 60B, and is released in the air. Consequently, heat can be released in a simple fashion, without introducing an additional metallic, resin or suchlike heat-sinking part.

Also, contact parts 50-52 of frame 40 are placed in direct contact with SDRAM 72, baseband IC 74 and RF tuner 74, so that it is not necessary to provide openings for checking a heat sink sheet in covers 60A and 60B. Consequently, it is possible to prevent dust from entering shield case 2 and improve the noise-robustness and air-tightness of circuit board 70. In addition, the structure of covers 60A and 60B can be simplified, so that covers 60A and 60B can be manufactured at ease.

Also, frame 40 has partitioning plate 422 that directly contacts grounding part 76 of circuit board 70. Consequently, it is possible to hold frame 40 at ground potential. Furthermore, partitioning plate 422 is placed in a location to match an edge of the connector 75 area provided on circuit board 70. Consequently, connector 75 and the circuit in shield case 2 can be shielded more firmly, and also partitioning plate 422 can reduce the stress that applies to circuit board 70 when connector 75 is plugged in and out.

Also, with circuit board 70, circuit elements of high calorific values, such as SDRAM 72, baseband IC 73 and RF tuner 74 are provided on one side of circuit board main body 71. By contrast with this, contact parts 50-52 of frame 40 are provided in locations to match circuit elements on one side where SDRAM 72, baseband IC 73 and RF tuner 74 are provided. In this way, it is possible to adopt a configuration to place contact parts 50-52 on only one side of circuit board 70, thereby allowing simplification of the structure of frame 10 and allowing easy manufacturing of frame.

Furthermore, coupling parts 42-47 and contact parts 50-52 of frame 40 are provided on the same side. By this means, it is possible to adopt a configuration to place coupling parts 42-47 and contact parts 50-52 on only one side of circuit board 70, thereby further simplifying the structure of frame 10 and allowing even easier manufacturing of frame 10.

The above description of an embodiment is only one example of an electronic device according to the present invention and is by no means limiting.

For example, although a configuration has been described above where frame 40 of the present embodiment has coupling parts 42-47 provided in the arrangement shown in FIG. 8, this is by no means limiting. It is equally possible to adopt a configuration in which frame connecting parts are provided to extend over the open plane of a circuit board and are arranged freely in a lattice pattern (substantially) in a side plate part. Furthermore, it is also possible to adopt a configuration in which contact parts are arranged freely in a side plate part in accordance with the arrangement of circuit elements on a circuit board.

In addition, with regards to other detailed configurations and operations of the electronic device of the above embodiment, various changes and modifications are possible without departing from the spirit of the present invention.

What is claimed is:

1. An electronic device comprising:
a circuit board with a circuit element disposed thereon; and
a shield case for accommodating the circuit board,
wherein the shield case has a frame which comprises a side plate part having a plurality of side plates for holding and covering an outer periphery of the circuit board, a coupling part extending parallel to the circuit board and connected to at least two of the side plates, and a contact part connected to the coupling part and directly contacting with the circuit element so that the shield case releases heat of the circuit element via the contact part and the connecting part.

2. The electronic device according to claim 1, wherein said circuit element is provided on at least one side of the circuit board, and said frame is arranged so that the coupling part and the contact part are placed on the one side of the circuit board.

3. The electronic device according to claim 1, wherein said circuit board further includes a grounding part with a ground potential on one side thereof, and said coupling part includes a partitioning plate directly contacting with the grounding part.

4. The electronic device according to claim 3, wherein said partitioning plate is arranged at a location corresponding to an edge of a connector area provided in the circuit board.

5. The electronic device according to claim 1, wherein said shield case further includes a cover for covering an uncovered part of the circuit board.
